(19) United States
(12) Patent Application Publication
(10) Pub. No.: US 2024/0234167 A1
(43) Pub. Date: Jul. 11, 2024

(54) MODULAR PRECURSOR DELIVERY AND SPLITTING FOR FAST SWITCHING

(71) Applicant: Applied Materials, Inc., Santa Clara, CA (US)

(72) Inventors: Shashank Sharma, Chhattisgarh (IN); Udit Suryakant Kotagi, Dharwad (IN); Diwakar Kedlaya, San Jose, CA (US); Mayur Govind Kulkarni, Bangalore (IN); Rupankar Choudhury, Agartala (IN)

(73) Assignee: Applied Materials, Inc., Santa Clara, CA (US)

(21) Appl. No.: 18/095,262

(22) Filed: Jan. 10, 2023

(51) Int. Cl. H01L 21/67

(52) U.S. Cl. CPC H01L 21/67017; H01L 21/67103; H01L 21/67196

(57) ABSTRACT

Exemplary substrate processing systems may include a lid plate. The systems may include a plurality of processing regions. The systems may include at least one splitter. Each splitter may include a top surface and side surfaces. Each splitter may define an inlet and a plurality of outlets. Each inlet and outlet may extend through a side surface. Each splitter may define an inlet lumen that extends from the fluid inlet to a hub. Each splitter may define a plurality of outlet lumens that each extend from the hub to one of the outlets. Each of the outlet lumens may have a same length. The systems may include a plurality of output manifolds. Each of the output manifolds may be coupled with a respective processing region. The systems may include a plurality of valves. At least one valve may be coupled between each outlet and an output manifold.

### TECHNICAL FIELD

The present technology relates to semiconductor processes and equipment. More specifically, the present technology relates to substrate processing systems and components.

### BACKGROUND

Semiconductor processing systems often utilize cluster tools to integrate a number of process chambers together. This configuration may facilitate the performance of several sequential processing operations without removing the substrate from a controlled processing environment, or it may allow a similar process to be performed on multiple substrates at once in the varying chambers. These chambers may include, for example, degas chambers, pretreatment chambers, transfer chambers, chemical vapor deposition chambers, physical vapor deposition chambers, etch chambers, metrology chambers, and other chambers. The combination of chambers in a cluster tool, as well as the operating conditions and parameters under which these chambers are run, are selected to fabricate specific structures using particular process recipes and process flows.

Oftentimes, processing systems include gas distribution systems that may mix and/or otherwise deliver a number of process gases to the various chambers. The flow of these gases may be carefully controlled to ensure uniform flow of gases into each of the processing chambers. Additionally, the gases may need to be maintained at certain temperatures during the gas delivery process.

Thus, there is a need for improved systems and methods that can be used to efficiently mix and/or otherwise deliver gases to processing chambers under desired conditions. These and other needs are addressed by the present technology.

### SUMMARY

Exemplary substrate processing systems may include a lid plate. The systems may include a plurality of processing regions disposed beneath the lid plate. The systems may include at least one fluid splitter seated on the lid plate. Each fluid splitter may include a top surface and a plurality of side surfaces. Each fluid splitter may define a fluid inlet and a plurality of fluid outlets. Each of the fluid inlet and the plurality of fluid outlets may extend through at least one of the plurality of side surfaces. Each fluid splitter may define an inlet lumen that extends from the fluid inlet to a central hub. Each fluid splitter may define a plurality of outlet lumens that each extend from the central hub to a respective one of the plurality of fluid outlets. Each of the plurality of outlet lumens may have a same length. The systems may include a plurality of output manifolds seated on the lid plate. Each of the plurality of output manifolds may be fluidly coupled with a respective one of the plurality of processing regions. The systems may include a plurality of valves. At least one valve may be fluidly coupled between each fluid outlet and a respective one of the plurality of output manifolds.

In some embodiments, the at least one fluid splitter may include a plurality of fluid splitters. The semiconductor processing system may include a plurality of fluid sources. Each of the plurality of fluid sources may be fluidly coupled with the fluid inlet of one of the plurality of fluid splitters. One of the plurality of fluid sources may include a purge gas source. At least one of the plurality of fluid sources may include a precursor fluid source. The plurality of fluid splitters may be arranged in a vertical stack. The plurality of valves may include multiple valves for each fluid outlet. The multiple valves for fluid gas outlet may be arranged in series with one another. The multiple valves for each fluid outlet may include a purge valve and at least one precursor valve. The purge valve may be disposed upstream of each of the at least one precursor valve. A single flow path may couple the multiple valves for each fluid outlet with a respective one of the plurality of output manifolds. A number of the multiple valves for each fluid outlet may match a number of the plurality of fluid splitters. Each fluid splitter may define a divert lumen that is fluidly coupled with the central hub. Each of the plurality of fluid outlets may include an orifice having a smaller diameter than an associated one of the plurality of outlet lumens. A number of the plurality of fluid outlets for each fluid splitter may match a number of the plurality of processing regions.

Some embodiments of the present technology may encompass fluid splitters. The fluid splitters may include a body having a top surface and a plurality of side surfaces. The body may define a fluid inlet and a plurality of fluid outlets. Each of the fluid inlet and the plurality of fluid outlets may extend through at least one of the plurality of side surfaces. The body may define an inlet lumen that extends from the fluid inlet to a central hub. The body may define a plurality of outlet lumens that each extend from the central hub to a respective one of the plurality of fluid outlets. Each of the plurality of outlet lumens may have a same length.

In some embodiments, the fluid splitter may include at least one heater cartridge disposed within the body. Each of the plurality of outlet lumens may be disposed at an equal distance from a respective one of the at least one heater. The body may define a divert lumen that is fluidly coupled with the central hub. Each of the plurality of fluid outlets may include an orifice having a smaller diameter than an associated one of the plurality of outlet lumens. Each of the plurality of outlet lumens may define a straight flow path. The body may define four fluid outlets and four outlet lumens. No fluid inlets or fluid outlets may extend through the top surface or a bottom surface of the body.

Some embodiments of the present technology may encompass semiconductor processing systems. The systems may include a lid plate. The systems may include a plurality of processing regions disposed beneath the lid plate. The systems may include at least one fluid splitter seated on the lid plate. Each fluid splitter may include a top surface and a plurality of side surfaces. Each fluid splitter may define a fluid inlet and a plurality of fluid outlets. Each of the fluid inlet and the plurality of fluid outlets may extend through at least one of the plurality of side surfaces. A number of the plurality of fluid outlets may match a number of the plurality of processing regions. Each fluid splitter may define an inlet lumen that extends from the fluid inlet to a central hub. Each fluid splitter may define a plurality of outlet lumens that each extend from the central hub to a respective one of the plurality of fluid outlets. Each of the plurality of outlet lumens may have a same length.

Such technology may provide numerous benefits over conventional systems and techniques. For example, the processing systems may provide multi-substrate processing capabilities that may be scaled well beyond conventional designs. For example, embodiments may provide a modular structure that enables a number of precursors to be adjusted simply by adding or subtracting a small set of modular components, which may help reduce the cost and complexity of gas delivery systems. Additionally, the processing systems may provide equal flow splitting between multiple chambers. Embodiments may provide simplified delivery path designs that reduce the amount of dead volume and enable fast switching between different precursors during processing operations. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to some embodiments of the present technology.

FIG. 2 shows a schematic isometric view of a transfer region of an exemplary chamber system according to some embodiments of the present technology.

FIG. 3 shows a schematic isometric view of a transfer region of an exemplary chamber system according to some embodiments of the present technology.

FIG. 4 shows a schematic isometric view of a transfer region of an exemplary chamber system according to some embodiments of the present technology.

FIG. 5 shows a schematic partial isometric view of a chamber system according to some embodiments of the present technology.

FIG. 6 shows a schematic top plan view of an exemplary processing system according to some embodiments of the present technology.

FIG. 7A shows a schematic top isometric view of an exemplary fluid splitter according to some embodiments of the present technology.

FIG. 7B illustrates a schematic top plan view of the fluid splitter of FIG. 7A.

FIG. 7C shows a partial schematic top plan view of an orifice coupled with the fluid splitter of FIG. 7A according to some embodiments of the present technology.

FIG. 8 shows an isometric view of a valve arrangement of the processing system of FIG. 6.

FIG. 8A shows a cross-sectional top plan view of a valve block arrangement of the processing system of FIG. 6.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

However, the use of a single gas source to deliver process gases to a number of chambers creates the possibility of uneven gas flow between the chambers. Additionally, due to manufacturing tolerances and flow path designs, conventional systems introduce opportunities for dead volumes of process gases and may be unsuitable for fast-switching of precursors during processing operations. For example, slight difference in cross-sectional area between flow paths to different chambers may be multiplied by the length of long flow paths to create noticeable flow conductance differences from chamber to chamber. These conductance differences may create the dead volumes. Conventional systems also utilize components that are designed for fixed numbers of precursors. To reduce the number of precursors used, existing flow paths must be blocked off, while adding precursors requires new components to be designed and fabricated. Thus, the scalability of existing gas delivery systems for multiple chambers is limited.

The present technology overcomes these issues by incorporating passive flow control devices that ensure flow from the gas source is equal between each chamber. Embodiments may implement modular fluid splitter designs that provide short and straight flow paths to each chamber to reduce the dead volume and to enable fast-switching between different precursors. The modular design may enable the number of precursors delivered to a set of chambers to be scaled up or down by adding or removing a small number of modular components including the fluid splitters and a number of valve blocks. The modular designs may also reduce the manufacturing complexity and cost of gas delivery components. Additionally, the present technology may incorporate an inert gas flow that creates a positive pressure flow that may be used to prevent backstreaming of different precursors.

Although the remaining disclosure will routinely identify specific structures, such as four-position chamber systems, for which the present structures and methods may be employed, it will be readily understood that the systems and methods are equally applicable to any number of structures and devices that may benefit from the structural capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

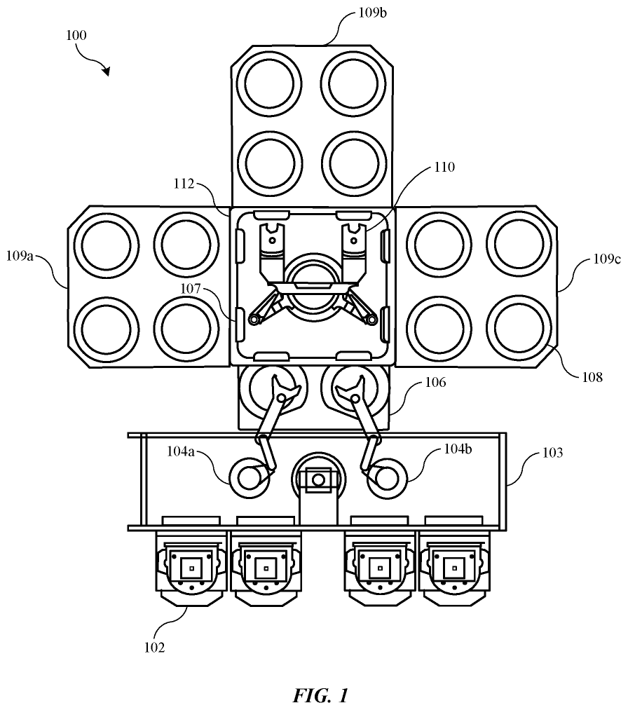

FIG. 1 shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

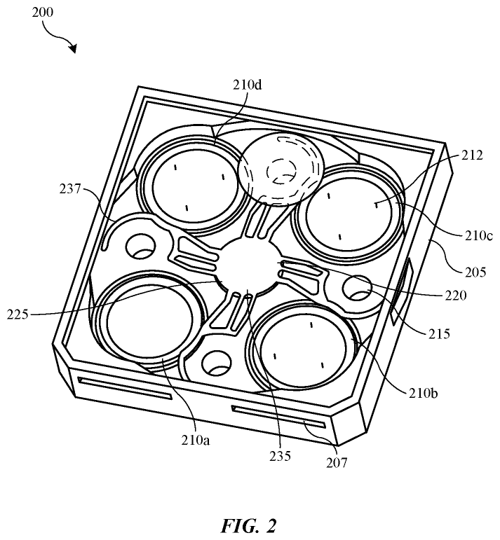

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region described above, and may include any of the components or characteristics described. The system illustrated may include a transfer region housing 205, which may be a chamber body as discussed further below, defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology. The transfer apparatus 220 may include a number of components and configurations that may facilitate the movement of the end effector in multiple directions, which may facilitate rotational movement, as well as vertical movement, or lateral movement in one or more ways with the drive system components to which the end effector may be coupled.

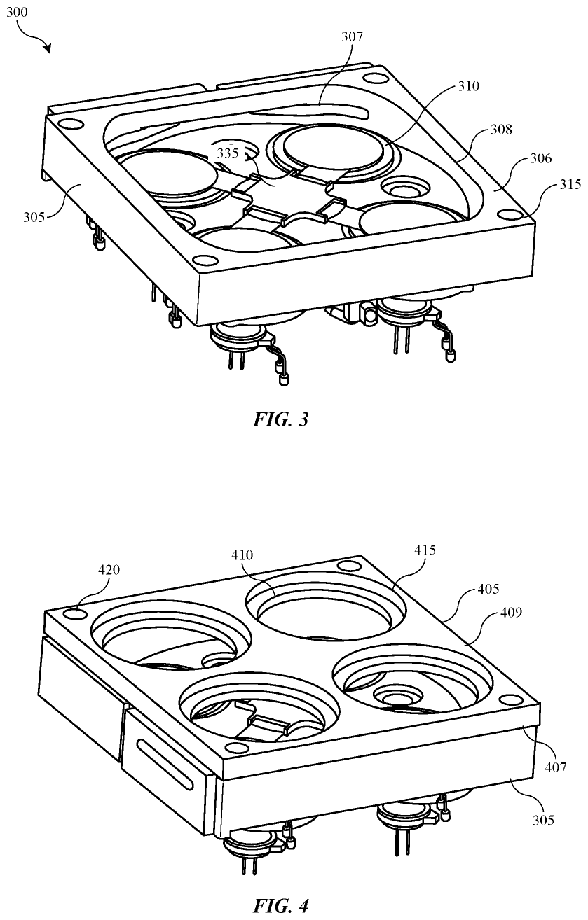

FIG. 3 shows a schematic isometric view of a transfer region of a chamber system 300 of an exemplary chamber system according to some embodiments of the present technology. Chamber system 300 may be similar to the transfer region of chamber system 200 described above, and may include similar components including any of the components, characteristics, or configurations described above. FIG. 3 may also illustrate certain component couplings encompassed by the present technology along with the following figures.

Chamber system 300 may include a chamber body 305 or housing defining the transfer region. Within the defined volume may be a plurality of substrate supports 310 distributed about the chamber body as previously described. As will be described further below, each substrate support 310 may be vertically translatable along a central axis of the substrate support between a first position illustrated in the figure, and a second position where substrate processing may be performed. Chamber body 305 may also define one or more accesses 307 through the chamber body. A transfer apparatus 335 may be positioned within the transfer region and be configured to engage and rotate substrates among the substrate supports 310 within the transfer region as previously described. For example, transfer apparatus 335 may be rotatable about a central axis of the transfer apparatus to reposition substrates. The transfer apparatus 335 may also be laterally translatable in some embodiments to further facilitate repositioning substrates at each substrate support.

Chamber body 305 may include a top surface 306, which may provide support for overlying components of the system. Top surface 306 may define a gasket groove 308, which may provide seating for a gasket to provide hermetic sealing of overlying components for vacuum processing. Unlike some conventional systems, chamber system 300, and other chamber systems according to some embodiments of the present technology, may include an open transfer region within the processing chamber, and processing regions may be formed overlying the transfer region. Because of transfer apparatus 335 creating an area of sweep, supports or structure for separating processing regions may not be available. Consequently, the present technology may utilize overlying lid structures to form segregated processing regions overlying the open transfer region as will be described below. Hence, in some embodiments sealing between the chamber body and an overlying component may only occur about an outer chamber body wall defining the transfer region, and interior coupling may not be present in some embodiments. Chamber body 305 may also define apertures 315, which may facilitate exhaust flow from the processing regions of the overlying structures. Top surface 306 of chamber body 305 may also define one or more gasket grooves about the apertures 315 for sealing with an overlying component. Additionally, the apertures may provide locating features that may facilitate stacking of components in some embodiments.

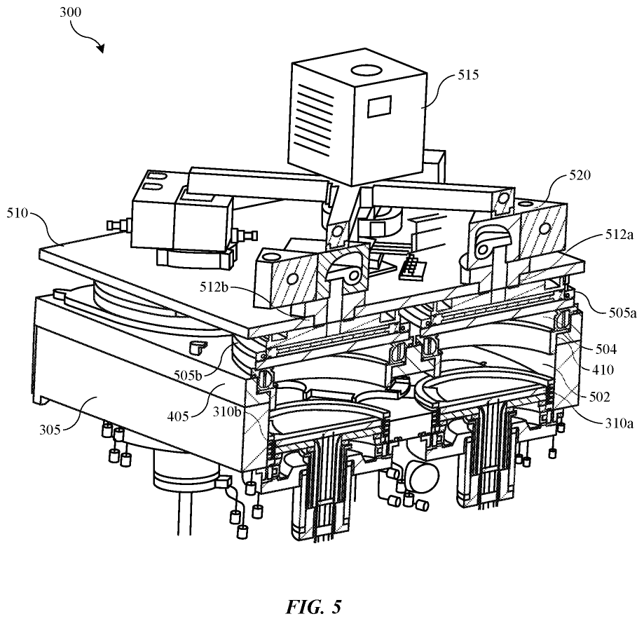

FIG. 4 shows a schematic isometric view of overlying structures of chamber system 300 according to some embodiments of the present technology. For example, in some embodiments a first lid plate 405 may be seated on chamber body 305. First lid plate 405 may by characterized by a first surface 407 and a second surface 409 opposite the first surface. First surface 407 of the first lid plate 405 may contact chamber body 305, and may define companion grooves to cooperate with grooves 308 discussed above to produce a gasket channel between the components. First lid plate 405 may also define apertures 410, which may provide separation of overlying regions of the transfer chamber to form processing regions for substrate processing.

Apertures 410 may be defined through first lid plate 405, and may be at least partially aligned with substrate supports in the transfer region. In some embodiments, a number of apertures 410 may equal a number of substrate supports in the transfer region, and each aperture 410 may be axially aligned with a substrate support of the plurality of substrate supports. As will be described further below, the processing regions may be at least partially defined by the substrate supports when vertically raised to a second position within the chamber systems. The substrate supports may extend through the apertures 410 of the first lid plate 405. Accordingly, in some embodiments apertures 410 of the first lid plate 405 may be characterized by a diameter greater than a diameter of an associated substrate support. Depending on an amount of clearance, the diameter may be less than or about 25% greater than a diameter of a substrate support, and in some embodiments may be less than or about 20% greater, less than or about 15% greater, less than or about 10% greater, less than or about 9% greater, less than or about 8% greater, less than or about 7% greater, less than or about 6% greater, less than or about 5% greater, less than or about 4% greater, less than or about 3% greater, less than or about 2% greater, less than or about 1% greater than a diameter of a substrate support, or less, which may provide a minimum gap distance between the substrate support and the apertures 410.

First lid plate 405 may also include a second surface 409 opposite first surface 407. Second surface 409 may define a recessed ledge 415, which may produce an annular recessed shelf through the second surface 409 of first lid plate 405. Recessed ledges 415 may be defined about each aperture of the plurality of apertures 410 in some embodiments. The recessed shelf may provide support for lid stack components as will be described further below. Additionally, first lid plate 405 may define second apertures 420, which may at least partially define pumping channels from overlying components described below. Second apertures 420 may be axially aligned with apertures 315 of the chamber body 305 described previously.

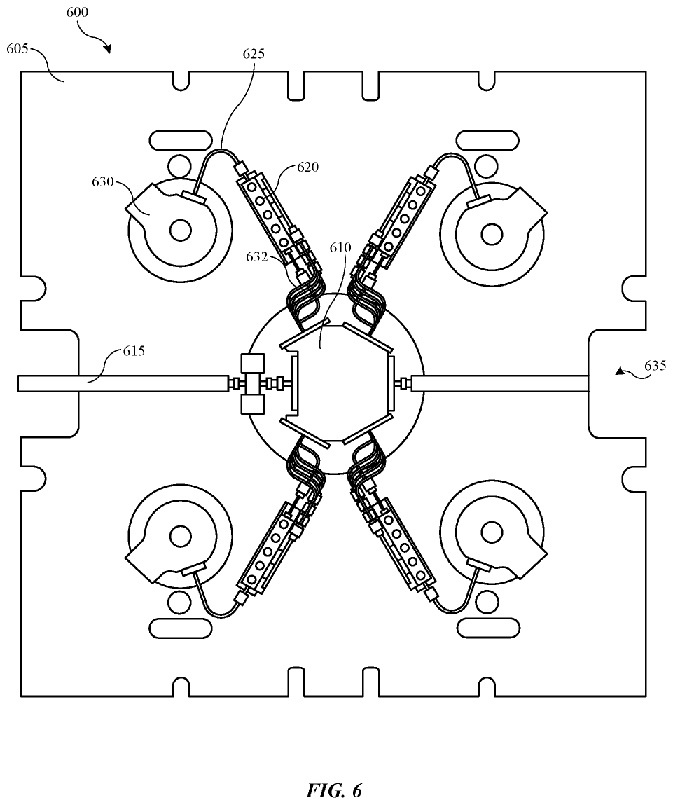

FIG. 5 shows a schematic partial isometric view of chamber system 300 according to some embodiments of the present technology. The figure may illustrate a partial cross-section through two processing regions and a portion of a transfer region of the chamber system. For example, chamber system 300 may be a quad section of processing system 100 described previously, and may include any of the components of any of the previously described components or systems.

Chamber system 300, as developed through the figure, may include a chamber body 305 defining a transfer region 502 including substrate supports 310, which may extend into the chamber body 305 and be vertically translatable as previously described. First lid plate 405 may be seated overlying the chamber body 305, and may define apertures 410 producing access for processing region 504 to be formed with additional chamber system components. Seated about or at least partially within each aperture may be a lid stack 505, and chamber system 300 may include a plurality of lid stacks 505, including a number of lid stacks equal to a number of apertures 410 of the plurality of apertures. Each lid stack 505 may be seated on the first lid plate 405, and may be seated on a shelf produced by recessed ledges through the second surface of the first lid plate. The lid stacks 505 may at least partially define processing regions 504 of the chamber system 300.

As illustrated, processing regions 504 may be vertically offset from the transfer region 502, but may be fluidly coupled with the transfer region. Additionally, the processing regions may be separated from the other processing regions. Although the processing regions may be fluidly coupled with other processing regions through the transfer region from below, the processing regions may be fluidly isolated, from above, from each of the other processing regions. Each lid stack 505 may also be aligned with a substrate support in some embodiments. For example, as illustrated, lid stack 505a may be aligned over substrate support 310a, and lid stack 505b may be aligned over substrate support 310b. When raised to operational positions, such as a second position, the substrates may deliver substrates for individual processing within the separate processing regions. When in this position, as will be described further below, each processing region 504 may be at least partially defined from below by an associated substrate support in the second position.

FIG. 5 also illustrates embodiments in which a second lid plate 510 may be included for the chamber system. Second lid plate 510 may be coupled with each of the lid stacks, which may be positioned between the first lid plate 405 and the second lid plate 510 in some embodiments. As will be explained below, the second lid plate 510 may facilitate accessing components of the lid stacks 505. Second lid plate 510 may define a plurality of apertures 512 through the second lid plate. Each aperture of the plurality of apertures may be defined to provide fluid access to a specific lid stack 505 or processing region 504. A remote plasma unit 515 may optionally be included in chamber system 300 in some embodiments, and may be supported on second lid plate 510. In some embodiments, remote plasma unit 515 may be fluidly coupled with each aperture 512 of the plurality of apertures through second lid plate 510. Isolation valves 520 may be included along each fluid line to provide fluid control to each individual processing region 504. For example, as illustrated, aperture 512a may provide fluid access to lid stack 505a. Aperture 512a may also be axially aligned with any of the lid stack components, as well as with substrate support 310a in some embodiments, which may produce an axial alignment for each of the components associated with individual processing regions, such as along a central axis through the substrate support or any of the components associated with a particular processing region 504. Similarly, aperture 512b may provide fluid access to lid stack 505b, and may be aligned, including axially aligned with components of the lid stack as well as substrate support 310b in some embodiments.

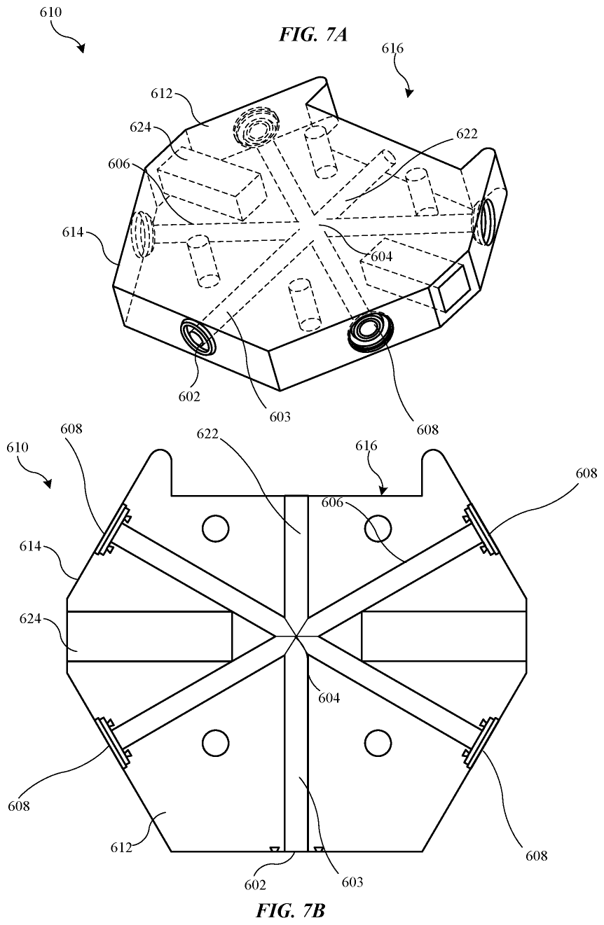

FIG. 6 shows a schematic top plan view of one embodiment of semiconductor processing system 600 according to some embodiments of the present technology. The figure may include components of any of the systems illustrated and described previously, and may also show further aspects of any of the previously described systems. It is to be understood that the illustration may also show exemplary components as would be seen on any quad section 109 described above.

Semiconductor processing system 600 may include a lid plate 605, which may be similar to second lid plate 510 previously described. For example, the lid plate 605 may define a number of apertures, similar to apertures 512, which provide access to a number of processing chambers and processing regions positioned beneath the lid plate 605. Each aperture of the plurality of apertures may be defined to provide fluid access to a specific lid stack, processing chamber, and/or processing region.

One or more fluid splitters 610 may be seated on a top surface of the lid plate 605. For example, the fluid splitter 610 may be centered between the apertures of the lid plate 605. Where multiple fluid splitters 610 are provided, the fluid splitters 610 may be stacked vertically, one atop another. Such a configuration may enable a footprint of the fluid splitters 610 to be reduced, while still enabling the number of different gas sources coupled with the chambers to be scaled up and down as will be discussed in greater detail below. In some embodiments, one or more polymer and/or other insulative spacers, such as PEEK spacers, may be provided between a bottom surface of a lowermost fluid splitter 610 and the lid plate 605. The spacers may help reduce heat transfer between the lowermost fluid splitter 610 and the lid plate 605, which may help improve process conditions and/or reduce power consumption of system 600 (such as by reducing the amount of power needed to heat the various fluid splitters 610). Each fluid splitter 610 may be fluidly coupled with a separate input weldment 615 or other fluid line that delivers a gas, such as a precursor, plasma effluent, and/or purge gas from a gas source to the fluid splitter 610. Each fluid splitter 610 may be fluidly coupled with a separate fluid source such that a different gas and/or liquid flows through each of the fluid splitters 610. For example, each of the input weldments 615 may extend vertically from fluid sources (such as a gas panel) positioned below the lid plate 605 and pass through a feedthrough plate. A portion of the input weldments 615 above the feedthrough plate may be bent horizontally and may direct the fluids toward the fluid splitter 610. In some embodiments, some or all of the input weldments 615 may be disposed within heater jackets that help prevent heat loss along the length of the input weldments 615.

As will be discussed further below, each fluid splitter 610 may receive a fluid from a respective input weldment 615 and may uniformly split the gas flows into a greater number of fluid outputs that are each interfaced with a respective one of a number of valves 620. The valves 620 may control the flow of each fluid to a given processing region. Each processing region may include its own dedicated set of valves 620. Multiple valves 620 (e.g., one for each fluid splitter 610) may be coupled with each processing region and may be arranged in series such that any combination of one or more fluids may be mixed and selectively delivered to the processing regions using only a single delivery line 625. For example, actuation of the valves 620 at each location may control whether purge and/or process fluids are mixed and/or flowed separately to a respective processing chamber. Each delivery line 625 (which may be a weldment in some embodiments) may deliver the fluid to an output manifold 630 associated with a particular processing chamber. For example, an output manifold 630 may be positioned over each aperture formed within the lid plate 605 and may be fluidly coupled with the lid stack components to deliver one or more gases to a processing region of a respective processing chamber. In some embodiments, one or more of the fluid splitters 610 may include a divert lumen and divert outlet that may be coupled with a divert line 635. The divert line 635 may be used to divert fluids (oftentimes liquids) away from the processing regions during one or more processing operations.

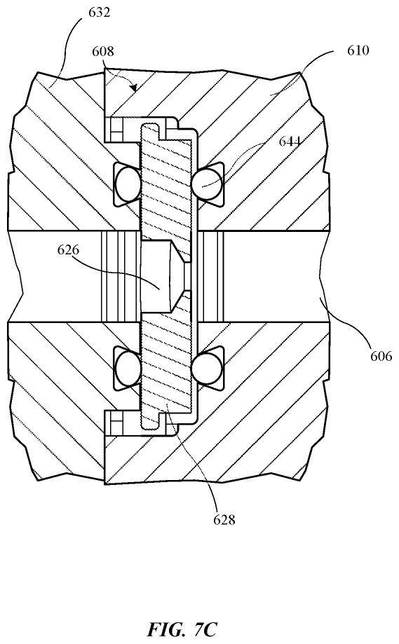

FIG. 7 shows a schematic isometric view of one fluid splitter 610. Fluid splitter 610 may include a body 616 having a top surface 612 and a number of side surfaces 614. In some embodiments, the fluid splitter 610 may be a monolithic structure, with any lumens and/or other apertures being machined into the structure. Such a design may eliminate the need for ebeam welding and/or other joining techniques that may present opportunities for gas leakage and/or uniformity issues. In some embodiments, each lumen/aperture machined into the fluid splitter 610 may be drilled or otherwise formed at an at least substantially (e.g., within 10 degrees, within 5 degrees, within 3 degrees, within 1 degree, or less) orthogonal angle relative to the exterior surface through which the lumen/aperture is formed. Each lumen may be at least substantially linear/straight. Such a design may improve the ease of fabrication and may help improve design tolerances and flow uniformity through the fluid splitter 610. As illustrated, the fluid splitter 610 is generally octagonal (with an indented side that includes two minor additional sides that define the distance of the indentation) in shape and has eight primary side surfaces 614, however other numbers of side surfaces 614 may be utilized in various embodiments to meet the needs of a particular application. As just one example, a number of side surfaces may be reduced for systems with fewer than four processing chambers and may be increased for systems with more than four processing chambers. The number of side surfaces may be selected such that each of a number of fluid outlets extends through a separate side surface 614 of the fluid splitter 610.

Fluid splitter 610 may be interfaced with one of the input weldments 615 as shown in FIG. 6. For example, the fluid splitter 610 may define a fluid inlet 602 that may couple with an outlet end of one of the input weldments 615, which may enable gas to be flowed from each gas source through the input weldments 615 and into the fluid splitter 610. In some embodiments, the fluid inlet 602 may extend through one of the side surfaces 614 of the fluid splitter 610. The fluid splitter 610 may define an inlet lumen 603 that extends between from the fluid inlet 602 and a hub 604 that splits flow from the fluid inlet 602 into a number of outlet lumens 606 that are defined within the body 616. The hub 604 may be positioned proximate a center of the body 606 in some embodiments. The outlet lumens 606 may each extend from the hub 604 to one of a number of fluid outlets 608. In some embodiments, each fluid outlet 608 may extend through one of the side surfaces 614. For example, each fluid outlet 608 may extend through a separate side surface 614. This may enable each outlet lumen 606 to have a same length (e.g., distance from the hub 604 to a respective one of the fluid outlets 608), which may help improve flow conductance uniformity to each chamber coupled with the fluid splitter 610. Additionally, by positioning the fluid inlet 602 and the fluid outlets 608 through a side surface 614 of the fluid splitter 610 (e.g., no fluid inlets 602 or fluid outlets 608 extend through the top surface 612 or a bottom surface of the body 616), multiple fluid splitters 610 may be stacked vertically, one atop another, which may reduce the footprint of the fluid splitters 610 on the lid plate 605.

As illustrated, four outlet lumens 606 are fluidly coupled with the fluid inlet 602 and extend radially outward from the hub 204 of the fluid splitter 610 to split flow from the input weldment 615 to deliver fluid to four (or other number based on a number of processing chambers/regions included in system 600) via the different fluid outlets 608. The number of outlet lumens 606 and fluid outlets 608 may match the number of processing chambers/regions included in system 600 in some embodiments such that flow of fluids to each processing chambers/region is passed through a separate, dedicated outlet lumen 606 and fluid outlet 608. The divert lumen 622 may have a same or different length and/or diameter than the outlet lumens 606.

It is to be understood that the arrangement of fluid inlet 602, fluid outlets 608, and fluid lumens 606 is merely representative of a single embodiment of a fluid splitter 610 and that numerous variations in placement and orientation of the fluid inlet 602, fluid outlets 608, and/or fluid lumens 606 are possible. Additionally, gas lumens 606 may be arranged to provide any number of flow paths. Fluid splitter 610 may be designed to accommodate any number of chambers/processing regions, allowing a single fluid source to deliver an equal flow of fluid to any number of processing chambers/regions.

In some embodiments, the fluid splitter 610 may include one or more heat sources. For example, one or more heater cartridges 624 may be coupled with and/or embedded within a body of the fluid splitter 610. In some embodiments, a number and arrangement of the heat cartridges 624 may be selected such that each outlet lumen 606 is equidistant from a respective heater cartridge 624, which may provide a uniform temperature gradient to each of the outlet lumens 606 of the fluid splitter 610. For example, as illustrated, two heater cartridges 624 are provided, with each heater cartridge 624 being positioned in between two adjacent outlet lumens 606, with the heater cartridges 624 being equidistant from the two adjacent outlet lumens 606 such that each outlet lumen 606 is the same distance from a heater cartridge 624. By providing a heat source within the fluid splitter 610, greater temperature control may be afforded to the system 600, which may improve the quality and uniformity of film deposition operations. For example, the improved temperature control (e.g., improved heating) may help ensure that the gases flowing through the weldments, fluid splitter 610, and/or other delivery channels of the processing system remain fully vaporized and have a lower risk of condensating within the fluid paths, which may help ensure better gas delivery uniformity from chamber to chamber. Additionally, the use of one or more heat sources in the fluid splitter 610 may help counteract any heat losses of the fluids as the fluids travel from the gas panel (or other fluid source) to the respective chambers/processing regions, as the heater jackets may not be able to fully prevent such heat losses. The heat sources may heat the fluid splitter 610 to temperatures of about or greater than 75° C., about or greater than 100° C., about or greater than 125° C., about or greater than 150° C., about or greater than 175° C., about or greater than 200° C., or more.

As best illustrated in FIG. 7C, the interfaces between the fluid outlets 608 and weldments or other fluid lines that deliver the fluid to the valves 620 and output manifolds 630 may include orifices 626 that choke the flow of gases and ensure that the flow conductance to each chamber/processing region is uniform (e.g., the flow is split substantially equally to each chamber within a given range of flow). The orifice 626 may be formed in a choke plate 628 or other material that defines the orifice 626 (e.g., an aperture) having a reduced diameter relative to a respective one of the outlet lumens 606. As illustrated, a choke plate 628 is secured between a fluid outlet 608 of fluid splitter 610 and a fluid line 632 that delivers the fluid to the valves 620 and output manifolds 630. The choke plate 628 may be received and secured within a slot and/or indentation formed at each fluid outlet 608. In some embodiments, one or more O-rings 644 may be used to seal an interface between a body of the choke plate 628 and faces of the fluid splitter 610 and/or fluid line 632 to prevent any fluids flowing through the choke plate 628 from leaking out of the interface. The choke plate 628 may define a central orifice 626 that has a diameter that is smaller than diameters of the fluid lumens 606. As illustrated, an upstream side of the central orifice 626 may have a smaller diameter than a downstream side of the central orifice 626. For example, a diameter of the central orifice 626 may taper and/or abruptly increase in diameter from the upstream side of the choke plate 628 to the downstream side. In other embodiments, the central orifice 626 may have a constant diameter across a thickness of the choke plate 628. The reduced diameter of the central orifice 626 relative to the diameters of fluid lumens 606 enables the central orifice 626 to serve as a passive flow control device that helps ensure that the flow conductance to each chamber/processing region is substantially uniform. The orifices 626 may also enable downstream components (including valves, output weldments, manifolds, lid stacks, etc.) to be modified or replaced without the need for any further flow rate tuning. Such modifications may be made without further flow rate tuning as long as the pressure upstream of the choke plates 628 stays the same at each interface of the fluid splitter 610 and the fluid lines 632, which may be achieved by maintaining the same sizes of central orifice 626 at each interface location. The choke point provided by the central orifice 626 ensures that the flow rate through the central orifice 626 is a function of only upstream pressure, as an amount of gas flowing through the choke point depends only on pressure upstream of the central orifices 626.

O-rings or gaskets may be seated between each component of the system 600. In particular, O-rings or gaskets may be seated between couplings of various gas lines, which may help seal the component connections and prevent gas leakage in some embodiments. It will be appreciated that various types of orifices and/or couplings may be used to control fluid flow through the fluid splitter 610. For example, the orifices may include machined fittings, vacuum coupling radiation (VCR) gaskets, and/or other fittings.

In operation, a fluid is flowed into the fluid splitter 610 via the fluid inlet 602, such as from a gas panel or other fluid source via an inlet line (such as input weldment 615). The fluid flows through inlet lumen 603 to hub 604, where the fluid is divided into a number of different streams, with each stream flowing through a different outlet lumen 606. The fluid may flow through each outlet lumen 606 and through an orifice 626 at each fluid outlet 608, with a flow rate and flow volume of the fluid being equal through each of the orifices 626 and fluid outlets 608.

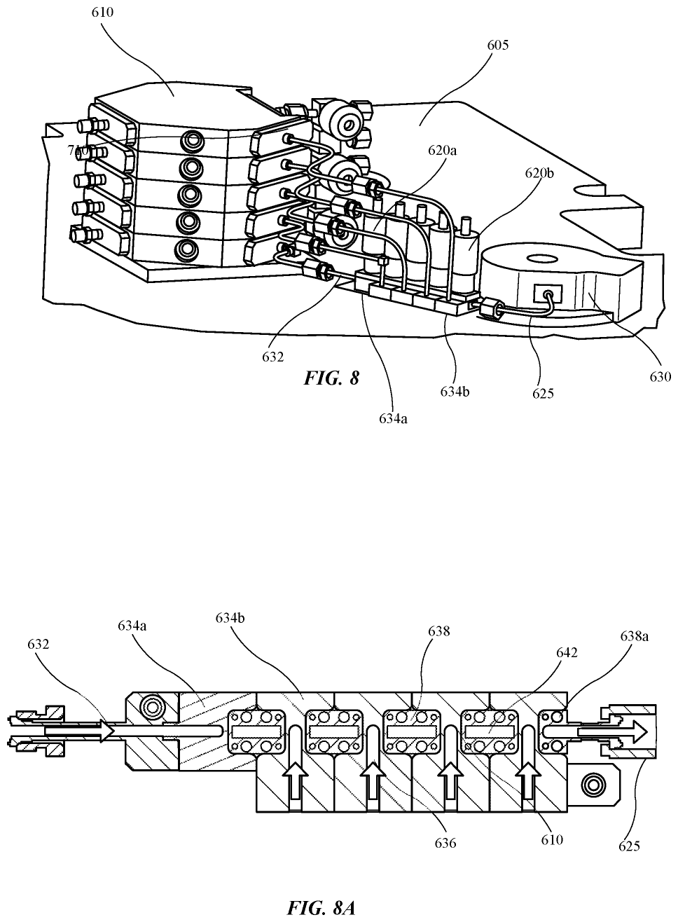

As indicated above, additional components may be used to fluidly couple and control flow from the fluid outlets 608 of the fluid splitter 610 to the output manifolds 630. FIG. 8 illustrates a partial schematic isometric view of a number of valves 620 interfaced between a number of fluid splitters 610 and an output manifold 630. As illustrated, five fluid splitters 610 are arranged on the lid plate 605, with the fluid splitters 610 being stacked vertically. The system 600 may include any number of fluid splitters 610. For example, the system 600 may include at least one fluid splitter, at least two fluid splitters, at least three fluid splitters, at least four fluid splitters, at least five fluid splitters, at least six fluid splitters, at least seven fluid splitters, at least eight fluid splitters, at least nine fluid splitters, at least ten fluid splitters, or more. Each fluid splitter 610 may receive a different fluid from a gas source (e.g., a gas panel). The fluids may include one or more inert purge gases, one or more precursors, and/or one or more other process or cleaning gases/liquids, with the various fluids coupled with the fluid splitters 610 in any arrangement. As illustrated, the bottommost fluid splitter 610 is coupled with an inert purge gas source, while the remaining fluid splitters 610 are each coupled with a different precursor. A fluid line 632 may extend between and fluidly couple each fluid outlet 608 with a different valve block 634, such that each fluid splitter 610 is coupled directly with a different valve block 634 and valve 620 (e.g., the number of valve blocks 634 and valves 620 for each chamber/processing region may match a number of the fluid splitters 610). As best illustrated in FIG. 8A, each valve block 634 may define a lumen 636 that extends between an inlet and a valve interface portion. A valve 620 may be positioned at valve interface portion to control the flow of each fluid to the output manifold 630.

In some embodiments, the valves 620 and valve blocks 634 for each output manifold 630 may be arranged in series, with a last valve block 634 in the series being coupled with a single delivery line 625 that delivers the fluid to the output manifold 630 through a single inlet of the output manifold. This arrangement may enable the flow of any combination of one or more of the fluids associated with the various fluid splitters 610 to be flowed to the output manifold 630 (and associated chamber/processing region) through the single delivery line 625. For example, each valve 620 associated with a given output manifold 630 may be in an open or closed position. An open valve 620 may enable the fluid from a particular fluid splitter 610 to pass to the output manifold 630. If a single valve 620 is open, only one fluid may be flowed to the output manifold 630, while multiple open valves 620 enable multiple fluids to be mixed and flowed to the output manifold 630 via the delivery line 625. In the illustrated embodiment, a purge gas valve 620a is disposed upstream of a number (here, four) precursor valves 620b. When fluids are flowed to the output manifold 630 and the corresponding chamber/processing region, the purge gas valve 620a may be opened to deliver an inert purge gas through the remaining valves 620b/valve blocks 634 to create a positive pressure through the series of valves 620/valve blocks 634. This positive pressure may help prevent the backstreaming of precursors flowing through open precursor valves 620b and may help prevent dead volumes. Any combination of the precursor valves 620b may be opened to introduce one or more precursors into the positive pressure stream of the purge gas, and the mixture of fluids may be flowed into the output manifold 630 and chamber/processing region.

In the illustrated embodiment, the purge valve 620a may be a two-way valve, while each of the precursor valves 620b may be three-way (e.g., three-port) valves, although other configurations are possible in various embodiments. The various valve blocks 634 may include two-way valve blocks 634a that enable a fluid to flow along a flow path having a single axis and three-way valve blocks 634b that enable a fluid to flow along two intersecting flow paths having different axes. The axes of the three-way valve blocks 634b may be orthogonal or at some other angle relative to one another. As shown, the purge valve 620a is coupled with a two-way valve block 634a, while the precursor valves 620b are each coupled with a respective three-way valve block 634b. Each three-way valve block 634b may have an identical structure, which may enable a number of precursors to be adjusted by simply adding or subtracting a number of fluid splitters 610, three-way valve blocks 634b (one for each fluid outlet 608 per fluid splitter 610 removed), and precursor valves 620b (one for each fluid outlet 608 per fluid splitter 610 removed), as well as intervening fluid lines (e.g., weldments, etc.). This provides a modular approach that enables the number of precursors available for processing operations to be easily scaled up or down by adding or subtracting a small number of modular components.

Each valve block 634 may be coupled with an adjacent valve block 634 via a coupling block 638, which may define a lumen 642 that may couple an outlet of one valve 620 and/or valve block 634 with the inlet of another valve 620 and/or valve block 634. The coupling blocks 638 may all have identical structures (which may improve the modularity of the system 600) with the exception of a downstream-most coupling block 638a, which may couple with the single delivery line 625.

While FIGS. 8 and 8A illustrate the connection between one fluid outlet 608 of each fluid splitter 610 and one output manifold 630, it will be appreciated that each output manifold 630 of system 600 may include a similar arrangement of valves 620 and valve blocks 634 to interface the output manifold 630 with a particular set of fluid outlets 608 of the fluid splitters 610 of system 610. It will be appreciated that the arrangement of fluid splitters 610, valves, 620, valve blocks 634, and output manifolds 630 described above is merely provided as one example and that numerous variations exist.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a lid plate;
a plurality of processing regions disposed beneath the lid plate;
at least one fluid splitter seated on the lid plate, each fluid splitter comprising a top surface and a plurality of side surfaces, wherein each fluid splitter defines:
a fluid inlet and a plurality of fluid outlets, with each of the fluid inlet and the plurality of fluid outlets extending through at least one of the plurality of side surfaces;
an inlet lumen that extends from the fluid inlet to a central hub; and
a plurality of outlet lumens that each extend from the central hub to a respective one of the plurality of fluid outlets, wherein each of the plurality of outlet lumens has a same length;
a plurality of output manifolds seated on the lid plate, each of the plurality of output manifolds being fluidly coupled with a respective one of the plurality of processing regions; and
a plurality of valves, wherein at least one valve is fluidly coupled between each fluid outlet and a respective one of the plurality of output manifolds.

2. The semiconductor processing system of claim 1, wherein:
the at least one fluid splitter comprises a plurality of fluid splitters; and
the semiconductor processing system comprises a plurality of fluid sources, each of the plurality of fluid sources being fluidly coupled with the fluid inlet of one of the plurality of fluid splitters.

3. The semiconductor processing system of claim 2, wherein:
one of the plurality of fluid sources comprises a purge gas source; and
at least one of the plurality of fluid sources comprises a precursor fluid source.

4. The semiconductor processing system of claim 2, wherein:
the plurality of fluid splitters are arranged in a vertical stack.

5. The semiconductor processing system of claim 1 wherein:
the plurality of valves comprise multiple valves for each fluid outlet; and
the multiple valves for fluid gas outlet are arranged in series with one another.

6. The semiconductor processing system of claim 5, wherein:
the multiple valves for each fluid outlet comprise a purge valve and at least one precursor valve; and
the purge valve is disposed upstream of each of the at least one precursor valve.

7. The semiconductor processing system of claim 5, wherein:
a single flow path couples the multiple valves for each fluid outlet with a respective one of the plurality of output manifolds.

8. The semiconductor processing system of claim 5, wherein:
a number of the multiple valves for each fluid outlet matches a number of the plurality of fluid splitters.

9. The semiconductor processing system of claim 1, wherein:
each fluid splitter defines a divert lumen that is fluidly coupled with the central hub.

10. The semiconductor processing system of claim 1, wherein:
each of the plurality of fluid outlets comprises an orifice having a smaller diameter than an associated one of the plurality of outlet lumens.

11. The semiconductor processing system of claim 1, wherein:
a number of the plurality of fluid outlets for each fluid splitter matches a number of the plurality of processing regions.

12. A fluid splitter, comprising:
a body having a top surface and a plurality of side surfaces, wherein the body defines:
a fluid inlet and a plurality of fluid outlets, with each of the fluid inlet and the plurality of fluid outlets extending through at least one of the plurality of side surfaces;
an inlet lumen that extends from the fluid inlet to a central hub; and
a plurality of outlet lumens that each extend from the central hub to a respective one of the plurality of fluid outlets, wherein each of the plurality of outlet lumens has a same length.

13. The fluid splitter of claim 12, further comprising:
at least one heater cartridge disposed within the body.

14. The fluid splitter of claim 13, wherein:
each of the plurality of outlet lumens is disposed at an equal distance from a respective one of the at least one heater.

15. The fluid splitter of claim 12, wherein:
the body defines a divert lumen that is fluidly coupled with the central hub.

16. The fluid splitter of claim 12, wherein:
each of the plurality of fluid outlets comprises an orifice having a smaller diameter than an associated one of the plurality of outlet lumens.

17. The fluid splitter of claim 12, wherein:
each of the plurality of outlet lumens defines a straight flow path.

18. The fluid splitter of claim 12, wherein:
the body defines four fluid outlets and four outlet lumens.

19. The fluid splitter of claim 12, wherein:
no fluid inlets or fluid outlets extend through the top surface or a bottom surface of the body.

20. A semiconductor processing system, comprising:
a lid plate;
a plurality of processing regions disposed beneath the lid plate; and
at least one fluid splitter seated on the lid plate, each fluid splitter comprising a top surface and a plurality of side surfaces, wherein each fluid splitter defines:
a fluid inlet and a plurality of fluid outlets, with each of the fluid inlet and the plurality of fluid outlets extending through at least one of the plurality of side surfaces, wherein a number of the plurality of fluid outlets matches a number of the plurality of processing regions;
an inlet lumen that extends from the fluid inlet to a central hub; and
a plurality of outlet lumens that each extend from the central hub to a respective one of the plurality of fluid outlets, wherein each of the plurality of outlet lumens has a same length.
